(19) United States
(12) Patent Application Publication
(10) Pub. No.: US 2024/0162881 A1
(43) Pub. Date: May 16, 2024

(54) ACOUSTIC WAVE DEVICE, FILTER, AND MULTIPLEXER

(71) Applicant: TAIYO YUDEN CO., LTD., Tokyo (JP)

(72) Inventors: Satoshi IMASU, Tokyo (JP); Ryohei KOMIYAMA, Tokyo (JP); Shinji YAMAMOTO, Tokyo (JP)

(73) Assignee: TAIYO YUDEN CO., LTD., Tokyo (JP)

(21) Appl. No.: 18/507,700

(22) Filed: Nov. 13, 2023

(30) Foreign Application Priority Data
Nov. 16, 2022 (JP) 2022-183192
Aug. 31, 2023 (JP) 2023-141449

(51) Int. Cl. H03H 9/02; H03H 9/25; H03H 9/64

(52) U.S. Cl. CPC H03H 9/02929; H03H 9/02015; H03H 9/25; H03H 9/6483

(57) ABSTRACT

An acoustic wave device includes a piezoelectric layer, and at least one pair of comb-shaped electrodes provided on the piezoelectric layer, each of the comb-shaped electrodes including electrode fingers each having a first layer and a second layer provided on the first layer, the first layer being a titanium nitride layer with a thickness greater than 50 nm, the second layer being a metal layer.

### CROSS-REFERENCE TO RELATED APPLICATION

This application is based upon and claims the benefit of priorities of the prior Japanese Patent Application No. 2022-183192, filed on Nov. 16, 2022, and the prior Japanese Patent Application No. 2023-141449, filed on Aug. 31, 2023, the entire contents of which are incorporated herein by reference.

### FIELD

A certain aspect of the present disclosure relates to an acoustic wave device, a filter, and a multiplexer.

### BACKGROUND

In systems for high-frequency communications, such as cellular phones, high-frequency filters are used to remove unnecessary signals outside the frequency bands used for communications. For example, surface acoustic wave (SAW) resonators are used for high-frequency filters. In the surface acoustic wave resonator, an interdigital transducer (IDT) having a plurality of electrode fingers is provided on a piezoelectric substrate such as a lithium tantalate substrate or a lithium niobate substrate. It is known to use an aluminum layer or an aluminum alloy layer as the electrode finger as disclosed in, for example, International Publication No. 2005-518127 (Patent Document 1) and Japanese Patent Application Laid-Open Nos. 2008-28980 and 2008-244523 (Patent Documents 2 and 3). It is known to provide a conformable layer of a titanium alloy or the like between the piezoelectric substrate and the aluminum layer or aluminum alloy layer, and to provide an intermediate layer of titanium nitride or the like between the conformable layer and the aluminum layer or aluminum alloy layer as disclosed in, for example, Patent Document 1.

### SUMMARY

The power durability can be improved by providing a titanium layer or the like between the piezoelectric substrate and a low-resistance metal layer such as an aluminum layer or an aluminum alloy layer. However, as the titanium layer is thickened, temperature characteristics such as the temperature coefficient of frequency (TCF) deteriorate.

The present invention has been made in view of the above problems, and an object thereof is to improve temperature characteristics.

In one aspect of the present disclosure, there is provided an acoustic wave device including: a piezoelectric layer; and at least one pair of comb-shaped electrodes provided on the piezoelectric layer, each of the comb-shaped electrodes including electrode fingers each having a first layer and a second layer provided on the first layer, the first layer being a titanium nitride layer with a thickness greater than 50 nm, the second layer being a metal layer.

In another aspect of the present disclosure, there is provided a filter including the above acoustic wave device.

In another aspect of the present disclosure, there is provided a multiplexer including the above filter.

### BRIEF DESCRIPTION OF THE DRAWINGS

FIG. 1A is a plan view of an acoustic wave device in accordance with an embodiment 1, and FIG. 1B is a cross-sectional view of electrode fingers in accordance with the embodiment 1;

FIG. 2A to FIG. 2D are cross-sectional views illustrating structures A to D in an experiment;

FIG. 3A to FIG. 3C are graphs illustrating the transmission characteristics of a filter in the structure A of a comparative example 1;

FIG. 4A to FIG. 4C are graphs illustrating the transmission characteristics of the filter in the structure A of the embodiment 1;

FIG. 5 illustrates normalized frequency variation with respect to ambient temperature in the structure A;

FIG. 6 is a graph illustrating the TCFs of the resonant frequency and the antiresonant frequency in the structures B to D of the comparative example 1 and the structures B to D of the embodiment 1;

FIG. 7 is a graph illustrating the TCF(fa) of the antiresonant frequency in the structure B of the comparative example 1 and the structure B of the embodiment 1;

FIG. 8A to FIG. 8C illustrate another exemplary structure of the acoustic wave resonator in the embodiment 1;

FIG. 9A and FIG. 9B illustrate other exemplary structures of the acoustic wave resonator in the embodiment 1;

FIG. 10A and FIG. 10B illustrate yet other exemplary structures of the acoustic wave resonator in the embodiment 1;

FIG. 11A is a circuit diagram of a filter in accordance with an embodiment 2, and FIG. 11B is a circuit diagram of a duplexer in accordance with a first variation of the embodiment 2;

and

FIG. 12A and FIG. 12B are cross-sectional views of a sensor element in accordance with an embodiment 3.

### DETAILED DESCRIPTION

Hereinafter, embodiments of the present disclosure will be described with reference to the drawings.

### Embodiment 1

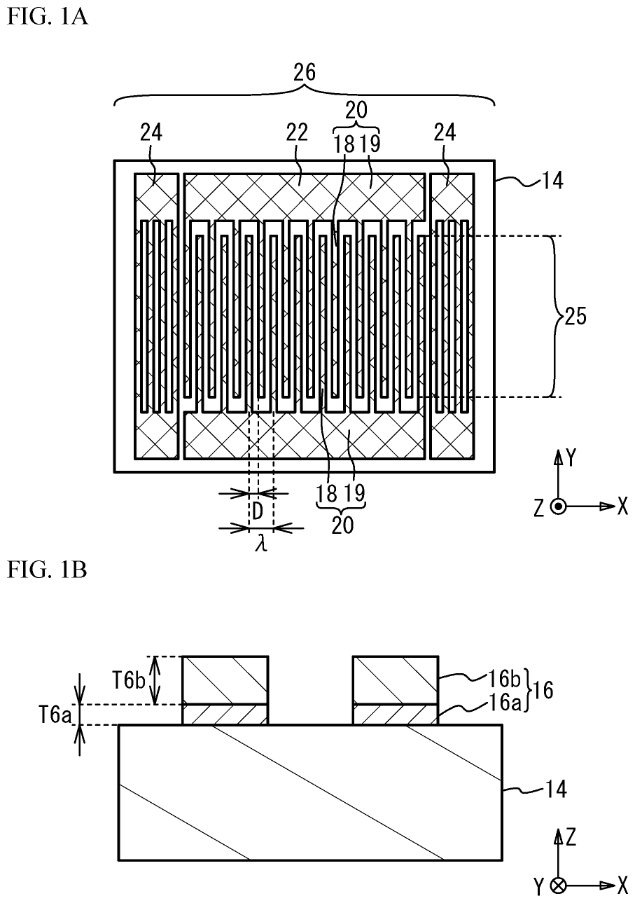

FIG. 1A is a plan view of an acoustic wave device in accordance with an embodiment 1, and FIG. 1B is a cross-sectional view of electrode fingers. The direction in which the electrode fingers are arranged (arrangement direction) is defined as an X direction, an extending direction of the electrode fingers is defined as a Y direction, and a stacking direction of a support substrate and a piezoelectric layer is defined as a Z direction. The X direction, the Y direction, and the Z direction do not necessarily correspond to the X-axis orientation and the Y-axis orientation of the crystal orientations of the piezoelectric layer. When the piezoelectric layer is a rotated Y-cut X-propagation substrate, the X direction is the X-axis orientation of the crystal orientations.

As illustrated in FIG. 1A, an acoustic wave resonator 26 is provided on a piezoelectric layer 14. The acoustic wave resonator 26 has an interdigital transducer (IDT) 22 and reflectors 24. The reflectors 24 are provided at respective sides of the IDT 22 in the X direction. The IDT 22 includes a pair of comb-shaped electrodes 20 opposing to each other. The comb-shaped electrode 20 includes a plurality of electrode fingers 18 and a bus bar 19 to which the electrode fingers 18 are connected. A region where the electrode fingers 18 of one the pair of the comb-shaped electrodes 20 and the electrode fingers 18 of the other of the pair of the comb-shaped electrodes 20 overlap when viewed from the X direction is an overlap region 25. The length of the overlap region 25 is the aperture length.

The electrode fingers 18 of one of the pair of the comb-shaped electrodes 20 and the electrode fingers 18 of the other of the pair of the comb-shaped electrodes 20 are alternately provided one by one in at least a part of the overlap region 25. The acoustic wave mainly excited by the electrode fingers 18 in the overlap region 25 propagates mainly in the X direction. The pitch of the electrode fingers 18 of one of the pair of the comb-shaped electrodes 20 is substantially equal to the wavelength λ of the acoustic wave. When the pitch of the electrode fingers 18 (the pitch between the centers of the electrode fingers 18) is represented by D, the pitch of the electrode fingers 18 of one of the comb-shaped electrodes 20 is two times the pitch D. The reflectors 24 reflect the acoustic wave excited by the electrode fingers 18 of the IDT 22. As a result, the acoustic wave is confined in the overlap region 25 of the IDT 22.

As illustrated in FIG. 1B, the IDT 22 such as the electrode fingers 18 and the reflectors 24 are formed of a conductive film 16 provided on the piezoelectric layer 14. The conductive film 16 includes a first layer 16a provided on the piezoelectric layer 14 and a second layer 16b provided on the first layer 16a. The thicknesses of the first layer 16a and the second layer 16b are represented by T6a and T6b, respectively.

The first layer 16a is a conductive polycrystalline or amorphous titanium nitride layer. The first layer 16a may contain intentional or unintentional impurities in addition to titanium (Ti) and nitride (N). The sum of the content percentage of titanium and the content percentage of nitrogen in the first layer 16a is, for example, 80 atomic % or greater, or 90 atomic % or greater. The ratio of the content percentage (atomic %) of nitrogen to the sum of the content percentage (atomic %) of titanium and the content percentage (atomic %) of nitrogen is, for example, 0.01 or greater and 0.99 or less, typically 0.3 or greater and 0.6 or less, more typically 0.38 or greater and 0.55 or less. When the titanium nitride is expressed by TiN_{X}, X in the titanium nitride layer is 0.01 or greater and 0.99 or less, typically 0.5 or greater and 1.5 or less, more typically 0.6 or greater and 1.2 or less.

The second layer 16b is a polycrystalline or amorphous aluminum (Al) layer or aluminum alloy layer. When the second layer 16b is an aluminum alloy layer, the second layer 16b contains at least one element selected from copper (Cu), magnesium (Mg), scandium (Sc), zirconium (Zr), titanium (Ti), neodymium (Nd), and silicon (Si) in addition to aluminum. When the second layer 16b is an aluminum layer, the second layer 16b may contain intentional or unintentional impurities in addition to aluminum. When the second layer 16b is an aluminum alloy layer, the second layer 16b may contain intentional or unintentional impurities in addition to aluminum and the metal element constituting the aluminum alloy. The content percentage of aluminum (Al) in the second layer 16b is, for example, 80 atomic % or greater, or 90 atomic % or greater. The second layer 16b may be a metallic layer such as a copper layer, a copper alloy layer, a molybdenum layer or a molybdenum alloy layer. When the second layer 16b is a copper layer, the second layer 16b may contain an intentional or unintentional impurity in addition to copper. When the second layer 16b is a copper alloy layer, the second layer 16b may contain an intentional or unintentional impurity in addition to the metal elements constituting the copper alloy. The content percentage of copper in the second layer 16b is, for example, 80 atomic % or greater, or 90 atomic % or greater.

### Experiment

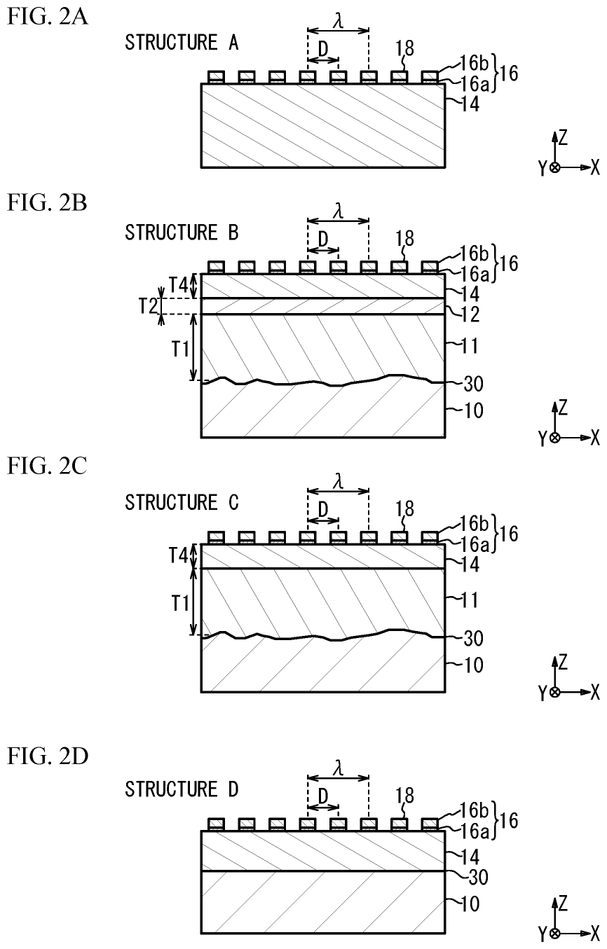

The acoustic wave resonators 26 having structures A to D were fabricated. FIG. 2A to FIG. 2D are cross-sectional views illustrating the structures A to D in an experiment, respectively. As illustrated in FIG. 2A, in the structure A, the conductive film 16 having the first layer 16a and the second layer 16b is provided on the piezoelectric layer 14. Neither an insulating layer nor a support substrate is provided under the piezoelectric layer 14.

As illustrated in FIG. 2B, in the structure B, an insulating layer 11 is provided on a support substrate 10, and the piezoelectric layer 14 is provided on an insulating layer 12. The insulating layer 12 is a temperature compensation film. The insulating layer 11 is a boundary layer. The temperature coefficient of frequency can be reduced by providing the insulating layer 12. Providing the insulating layer 11 allows the surface acoustic wave of the main mode to be confined in the piezoelectric layer 14 and the insulating layer 12, and reduces the spurious emission caused by the unnecessary wave. An interface 30 between the support substrate 10 and the insulating layer 11 is a rough surface. Thereby, the unnecessary wave is scattered at the interface 30, and the spurious emission can be reduced. Other interfaces are mirrored surfaces. The thicknesses of the insulating layers 11 and 12 and the piezoelectric layer 14 are represented by T1, T2 and T4, respectively. Other configurations are the same as those of the structure A in FIG. 2A, and the description thereof is omitted.

As illustrated in FIG. 2C, in the structure C, the insulating layer 12 is not provided. Other configurations are the same as those of the structure B in FIG. 2B, and the description thereof is omitted. As illustrated in FIG. 2D, in the structure D, neither insulating layer 11 nor 12 is provided, and the interface 30 is a mirrored surface. Other configurations are the same as those of the structure B of FIG. 2B, and the description thereof will be omitted. The arithmetic average roughness Ra of the rough surface is, for example, larger than 10 nm and 100 nm or less, and the arithmetic average roughness Ra of the mirrored surface is, for example, 10 nm or less and is about 1 nm. The irregularities on the rough surface may be random or periodic.

The fabrication conditions for the structures A to D were as follows.
Conditions common to the structures A to D
   Piezoelectric layer 14: 42° Y-cut X-propagation lithium tantalate substrate
   First layer 16a: Embodiment 1: titanium nitride, Comparative example 1: titanium
   Second layer 16b: Aluminum-copper alloy
   T6a: 60 nm
   T6b: 90 nm
   Wavelength λ (2×D) of the acoustic wave: 1.5 μm
Structure B
   Support substrate 10: Sapphire substrate having a thickness of 500 μm and having a rough interface 30
   Insulating layer 12: Silicon oxide layer having a thickness T2 of 0.2λ
   Piezoelectric layer 14: Thickness T4 is 0.3λ
Structure C
   Support substrate 10: Sapphire substrate having a thickness of 500 μm and having a rough interface 30
   Insulating layer 11: Aluminum oxide layer having a thickness T1 of 5λ
   Piezoelectric layer 14: Thickness T4 is 0.3λ
Structure D
   Support substrate 10: Sapphire substrate having a thickness of 500 μm and having a mirrored interface 30
   Piezoelectric layer 14: Thickness T4 is 13λ

[Temperature Characteristics of Ladder Filter with Structure A]

A ladder-type filter including the acoustic wave resonator having the structure A was fabricated, and the temperature dependence of the transmission characteristics of the filter was measured.

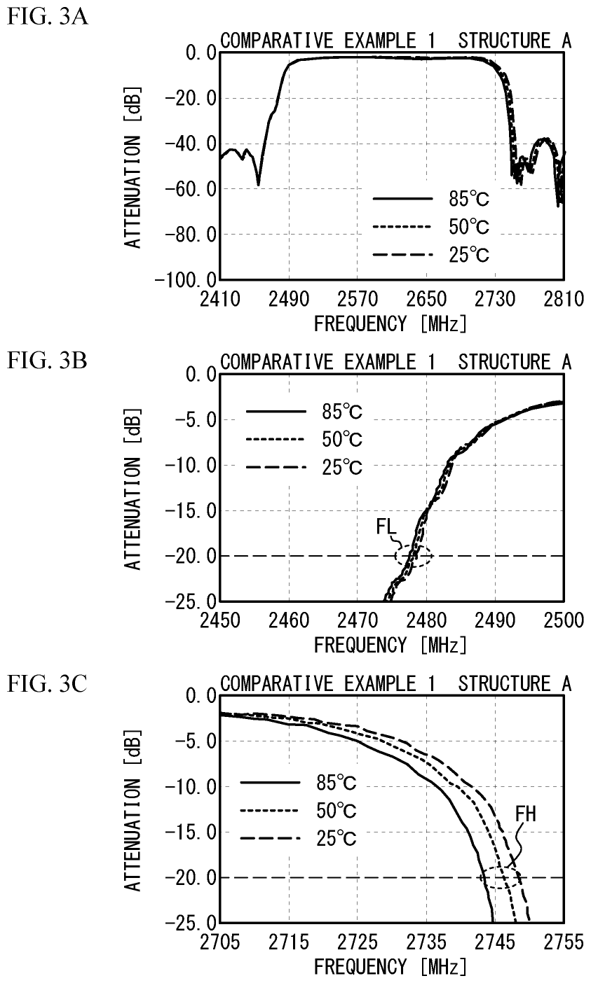

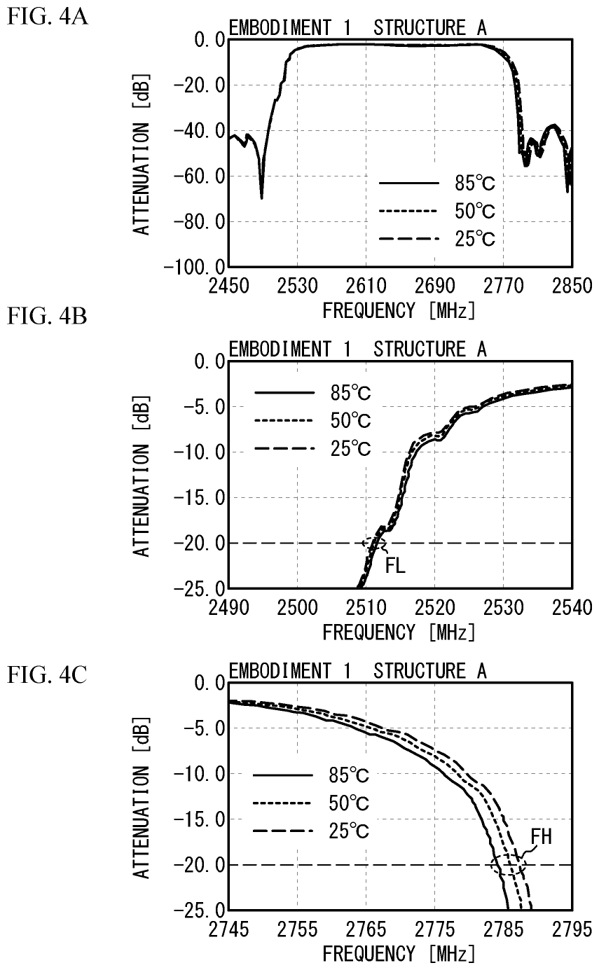

FIG. 3A to FIG. 3C are graphs illustrating the transmission characteristics of the filter in the structure A of the comparative example 1. FIG. 4A to FIG. 4C are graphs illustrating the transmission characteristics of the filter in the structure A of the embodiment 1. FIG. 3B and FIG. 4B are enlarged views of the low-frequency-side shoulder of the passband, and FIG. 3C and FIG. 4C are enlarged views of the high-frequency-side shoulder of the passband. The transmission characteristics at ambient temperatures of 85° C., 50° C., and 25° C. are presented.

As illustrated in FIG. 3A to FIG. 4C, as the temperature increases, the frequencies of the low-frequency-side shoulder and the high-frequency-side shoulder decrease. The change in the frequency of the high frequency shoulder with respect to the temperature is greater than the change in the frequency of the low frequency shoulder with respect to temperature. The frequency of the low-frequency-side shoulder at attenuation of −20 dB is represented by FL, and the frequency of the high-frequency-side shoulder at attenuation of −20 dB is represented by FH. The TCF of the frequency FL is represented by TCFL and the TCF of the frequency FH is represented by TCFH.

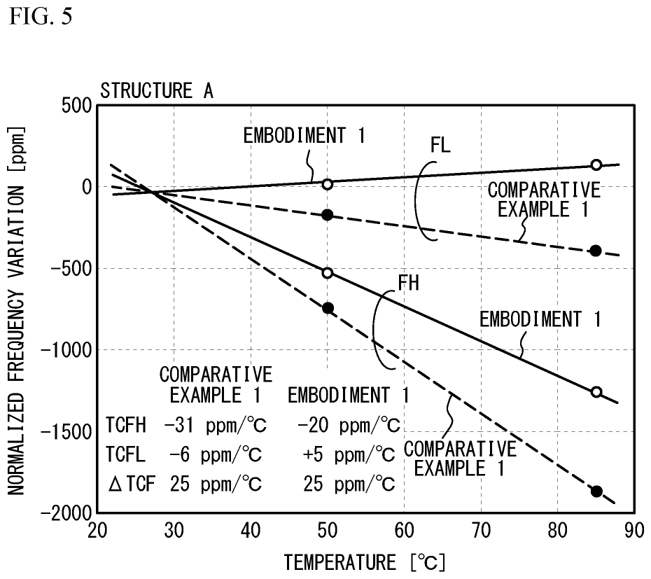

FIG. 5 presents normalized frequency variation with respect to ambient temperature in the structure A. The normalized frequency variation is an index indicating a variation in frequency normalized by the frequency at about 25° C. The slope of the normalized frequency variation with respect to the ambient temperature is the TCF. In the comparative example 1, TCFH and TCFL are −31 ppm/° C. and −6 ppm/° C., respectively. ΔTCF=TCFL−TCFH is 25 ppm/° C.

In the embodiment 1, TCFH and TCFL are −20 ppm/° C. and +5 ppm/° C., respectively. ΔTCF=TCFL−TCFH is 25 ppm/° C. As described above, in the embodiment 1, TCFH and TCFL are shifted to more positive sides than those of the comparative example 1. ΔTCF in the embodiment 1 is substantially equal to ΔTCF in the comparative example 1.

[Temperature Dependence of Acoustic Wave Resonators with Structures B to D]

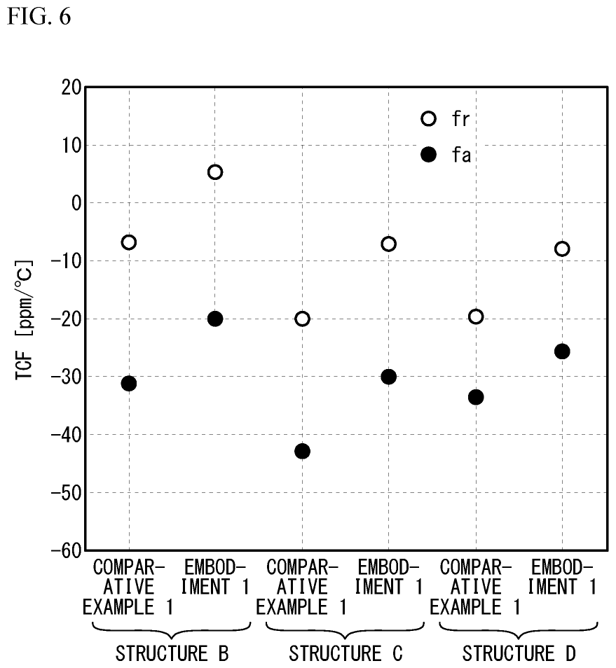

Acoustic wave resonators having the structures B to D were fabricated, and the TCFs of the resonant frequency fr and the antiresonant frequency fa were measured. FIG. 6 is a graph presenting the TCFs of the resonant frequencies and the antiresonant frequencies in the structures B to D of the comparative example 1 and the structures B to D of the embodiment 1. Dots indicate average values of nine acoustic wave resonators. A white circle indicates the TCF of the resonant frequency fr, and a black circle indicates the TCF of the antiresonant frequency fa. As presented in FIG. 6, in all of the structures B to D, the TCF of the antiresonant frequency fa is less than the TCF of the resonant frequency fr, and the absolute value of the TCF of the antiresonant frequency fa is larger than that of the TCF of the resonant frequency fr.

In both the comparative example 1 and the embodiment 1, the absolute value of the TCF of the antiresonant frequency fa is larger in the structure C than in the structure D. This is considered because the piezoelectric layer 14 is thinned to λ or less and the insulating layer 11 is provided in order to reduce loss and spurious emissions. The absolute value of the TCF is smaller in the structure B than in the structure C, and the absolute value of the TCF is smaller in the structure B than in the structure D. This is considered because the insulating layer 12 is provided as a temperature compensation film.

In any of the structures B to D, the absolute value of the TCF is smaller in the embodiment 1 than in the comparative example 1. As clear from the above, the TCF can be improved in the embodiment 1 regardless of the structure.

[Temperature Dependence when the Thickness of the First Layer is Varied in the Structure B]

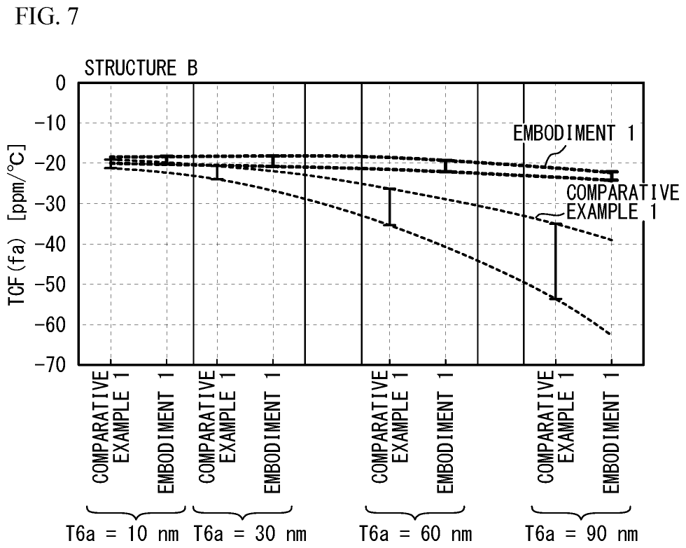

For the structure B, the TCF of the antiresonant frequency fa was measured for different thicknesses T6a of the first layer 16a. FIG. 7 is a graph presenting the TCF(fa) of the antiresonant frequency in the structure B of the comparative example 1 and the structure B of the embodiment 1. The horizontal axis corresponds to the thickness T6a of the first layer 16a, but the horizontal axis is shifted between the comparative example 1 and the embodiment 1. The TCF(fa) of each of the nine acoustic wave resonators was measured, and the error bars indicate the maximum value and the minimum value of the TCF(fa) of the nine acoustic wave resonators, where larger error bars indicate larger variations. The thicknesses T6a are 10 nm, 30 mm, 60 nm, and 90 nm, and the dotted curve connecting the error bars is illustrated.

As presented in FIG. 7, in the comparative example 1, when the thickness T6a is 10 nm, the TCF(fa) is about −20 ppm/° C. When the thickness T6a is 30 nm, the TCF(fa) is about −20 ppm/° C., and the variation is slightly large. When the thickness Ta is 60 nm, the TCF(fa) is −30 ppm/° C., and the variation is large. When the thickness Ta is 90 nm, the TCF(fa) is −40 to −50 ppm/° C., and the variation is further increased.

In the embodiment 1, when the thickness T6a is 10 nm, the TCF(fa) is about −20 ppm/° C., which is substantially the same as that of the comparative example 1. The variation is also substantially the same as that of the comparative example 1. When the thickness T6a is 30 nm or 60 nm, the TCF(fa) and the variation are almost the same as when T6a is 10 nm. When the thickness T6a is 90 nm, the TCF(fa) is −22 ppm/° C., which is slightly more negative than when T6a is 10 nm. The variation is substantially the same when T6a is 10 nm.

As described above, in the comparative example 1, as the thickness T6a of the first layer 16a is increased, the TCF is deteriorated and the variation is also increased. On the other hand, in the embodiment 1, the TCF and the variation thereof hardly change even when the thickness T6a is increased. The TCF in the comparative example 1 starts to deteriorate and the variation starts to increase when the thickness T6a becomes larger than 30 nm.

To improve the power durability of the electrode fingers 18, the thickness T6a may be made thicker. To make the electrode fingers 18 heavy and not thick, the thickness T6a may be increased. For such cases, in the comparative example 1, the TCF deteriorates and the variation increases. In the embodiment 1, even when the thickness T6a is increased, the deterioration in the TCF and the increase in the variation of the TCF can be reduced.

The reason why the deterioration in the TCF can be reduced even when the thickness T6a is increased in the embodiment 1 is not clear, but is considered as follows. The Young's moduli of titanium (or titanium nitride) and aluminum constituting the electrode fingers 18 vary with temperature and are larger than the change in the Young's modulus of the piezoelectric layer 14 with respect to temperature. In the comparative example 1, the change in the Young modulus of the first layer 16a with respect to the temperature is larger than the change in the Young modulus of the second layer 16b with respect to the temperature, and as the thickness of the first layer 16a is increased, the TCF deteriorates. In the embodiment 1, it is considered that since the Young's modulus of titanium nitride is larger than the Young's modulus of titanium, even if the Young's moduli of the first layer 16a and the second layer 16b change with temperature, the first layer 16a is less likely to deform, and thus the deterioration in the TCF is reduced.

In summary, when a titanium layer is used as the first layer 16a and an aluminum layer or an aluminum alloy layer is used as the second layer 16b as in the comparative example 1, the TCF deteriorates when the thickness T6a of the first layer 16a is larger than 30 nm. Therefore, the second layer 16b is a titanium nitride layer. As a result, deterioration in the TCF can be reduced.

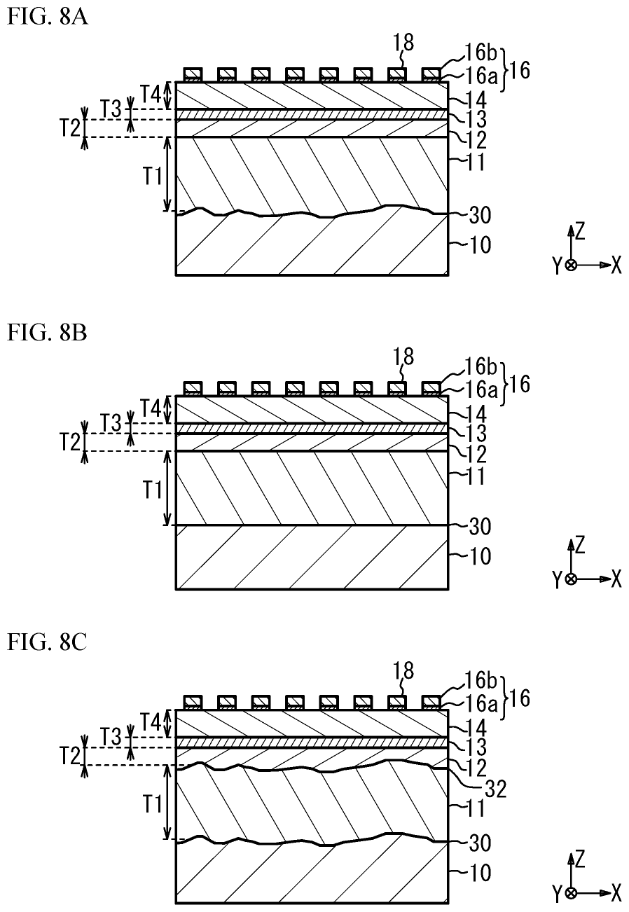

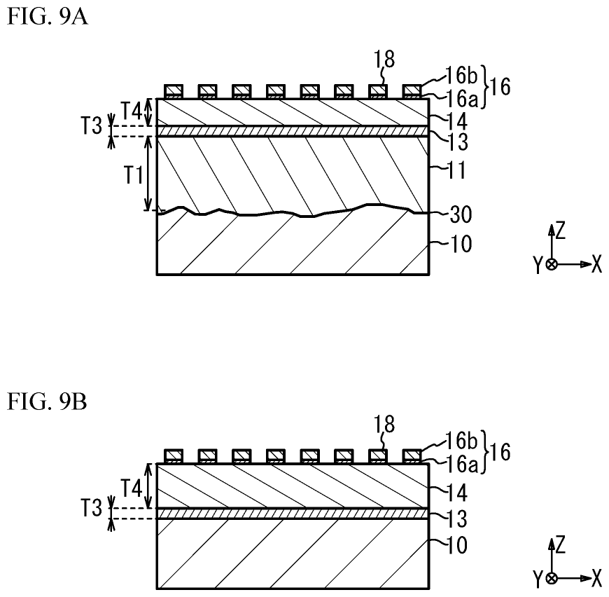

FIG. 8A to FIG. 9B illustrate other exemplary structures of the acoustic wave resonator in the embodiment 1. As illustrated in FIG. 8A, an insulating layer 13 may be provided between the insulating layer 11 and the piezoelectric layer 14. The insulating layer 13 is a layer that bonds the piezoelectric layer 14 and the insulating layer 11. For example, when the insulating layer 11 and the piezoelectric layer 14 are bonded using a surface activation method, the insulating layer 13 is provided when the insulating layer 11 and the piezoelectric layer 14 are difficult to bond directly. Other configurations are the same as those of FIG. 2B, and the description thereof is omitted.

As illustrated in FIG. 8B, the interface 30 between the support substrate 10 and the insulating layer 11 may be a mirrored surface. Other configurations are the same as those in FIG. 8A, and the description thereof is omitted. As illustrated in FIG. 8C, an interface 32 between the insulating layers 11 and 12 may be a rough surface. Other configurations are the same as those in FIG. 8A, and the description thereof is omitted.

As illustrated in FIG. 9A, the insulating layer 13 may be provided as a bonding layer between the insulating layer 11 and the piezoelectric layer 14. Other configurations are the same as those of FIG. 2C, and the description thereof is omitted. As illustrated in FIG. 9B, the insulating layer 13 may be provided as a bonding layer between the support substrate 10 and the piezoelectric layer 14. Other configurations are the same as those of FIG. 2D, and the description thereof is omitted.

In FIG. 2A to FIG. 2D and FIG. 8A to FIG. 9B, the piezoelectric layer 14 is, for example, a monocrystalline lithium tantalate (LiTaO₃) substrate or a monocrystalline lithium niobate (LiNbO₃) substrate, and is, for example, a rotated Y-cut X-propagation lithium tantalate layer or a rotated Y-cut X-propagation lithium niobate layer. The piezoelectric layer 14 may be a monocrystalline quartz substrate. In particular, when the piezoelectric layer 14 is a 36° or greater and 50° or less rotated Y-cut X-propagation lithium tantalate layer, a shear horizontal (SH) wave is excited as an acoustic wave in a main mode.

In FIG. 2B to FIG. 2D and FIG. 8A to FIG. 9B, the support substrate 10 is, for example, a sapphire substrate, an alumina substrate, a silicon substrate, a spinel substrate, a crystal substrate, a quartz substrate, or a silicon carbide substrate. The sapphire substrate is a monocrystalline Al₂O₃ substrate, the alumina substrate is a polycrystalline or amorphous Al₂O₃ substrate, the silicon substrate is a monocrystalline or polycrystalline silicon substrate, the spinel substrate is a polycrystalline or amorphous MgAl₂O₄ substrate, the quartz substrate is a monocrystalline SiO₂ substrate, the quartz substrate is a polycrystalline or amorphous SiO₂ substrate, and the silicon carbide substrate is a polycrystalline or monocrystalline SiC substrate. The linear expansion coefficient of the support substrate 10 in the X direction is smaller than the linear expansion coefficient of the piezoelectric layer 14 in the X direction. Thus, the frequency temperature dependence of the acoustic wave resonator can be reduced. The acoustic velocity of the bulk wave propagating through the support substrate 10 may be higher or lower than the acoustic velocity of the bulk wave propagating through the piezoelectric layer 14 and the insulating layers 11 to 13.

The thickness T4 of the piezoelectric layer 14 is preferably 1λ, or less, and more preferably 0.5λ or less to reduce spurious emissions and loss. When the piezoelectric layer 14 is too thin, it becomes difficult to excite an acoustic wave. Therefore, the thickness T4 is preferably 0.1λ or greater.

In FIG. 2B and FIG. 8A to FIG. 8C, the acoustic velocity of the bulk wave propagating through the insulating layer 11 is higher than the acoustic velocity of the bulk wave propagating through the insulating layer 12 and the piezoelectric layer 14. As a result, the energy of the acoustic wave of the main response is confined in the piezoelectric layer 14 and the insulating layer 12. The insulating layer 11 is polycrystalline or amorphous, for example, and is an aluminum oxide layer, a silicon nitride layer, an aluminum nitride layer, a silicon film, or a silicon carbide layer. To confine the acoustic wave in the insulating layer 12 and the piezoelectric layer 14, the thickness T1 of the insulating layer 11 is preferably 0.3λ or greater, more preferably Iλ or greater. To improve the characteristics, each thickness T1 is preferably 10λ or less.

The insulating layer 12 is, for example, a temperature compensation film and has a temperature coefficient of an elastic constant that is opposite in sign to the temperature coefficient of the elastic constant of the piezoelectric layer 14. For example, the temperature coefficient of the elastic constant of the piezoelectric layer 14 is negative while the temperature coefficient of the elastic constant of the insulating layer 12 is positive. The insulating layer 12 is an insulating layer containing silicon oxide (SiO₂) as a main component and is, for example, a silicon oxide layer containing no additive element or an additive element such as fluorine, and is, for example, polycrystalline or amorphous. The insulating layer 12 is not limited to a polycrystalline or amorphous silicon oxide layer, but may be made of monocrystalline quartz (SiO₂). Thus, the temperature coefficient of frequency of the acoustic wave resonator can be reduced. When the insulating layer 12 is a silicon oxide layer, the acoustic velocity of the bulk wave propagating through the insulating layer 12 is lower than the acoustic velocity of the bulk wave propagating through the piezoelectric layer 14.

In order for the insulating layer 12 to have the temperature compensation function, the energy of the acoustic wave of the main response is required to be present to some extent in the insulating layer 12. Although the section in which the energy of the surface acoustic wave is concentrated depends on the type of the surface acoustic wave, the energy of the surface acoustic wave is typically concentrated in the section from the upper surface of the piezoelectric layer 14 to a depth of 2λ (λ is the wavelength of the surface acoustic wave), and particularly concentrated in the section from the upper surface of the piezoelectric layer 14 to a depth of λ. Therefore, the distance (thickness T2+thickness T4) from the lower surface of the insulating layer 12 to the upper surface of the piezoelectric layer 14 is preferably 2λ, or less, and more preferably 1λ, or less.

The insulating layer 13 is, for example, a bonding layer, and is a layer that bonds the insulating layer 12 and the piezoelectric layer 14. When the insulating layer 13 is a silicon oxide film, it is difficult to directly bond the piezoelectric layer 14 and the insulating layer 12 to each other using a surface activation method. In such a case, an insulating layer made of a material different from that of the insulating layer 12 is provided as the insulating layer 13. The insulating layer 13 is polycrystalline or amorphous, for example, and is an aluminum oxide film, a silicon nitride film, an aluminum nitride film, a silicon film, or a silicon carbide film. In order to confine the energy of the acoustic wave in the piezoelectric layer 14, the thickness T3 of the insulating layer 13 is preferably 100 nm or less. In order to allow the insulating layer 13 to function as a bonding layer, the thickness T3 is preferably 1 nm or greater.

The wavelength λ of the acoustic wave is, for example, 1 μm to 6 μm. When the two electrode fingers 18 are defined as one pair, the number of pairs of the electrode fingers 18 is, for example, 20 to 300. The duty ratio of the IDT 22 is calculated by (the width of the electrode finger 18)/(the pitch of the electrode fingers 18), and is, for example, 30% to 70%. The aperture length of the IDT 22 is, for example, 10λ to 50λ. The wavelength λ of the acoustic wave is twice the average pitch D of the electrode fingers 18. The average pitch D of the electrode fingers 18 can be calculated by dividing the width of the IDT 22 in the X direction by the number of the electrode fingers 18.

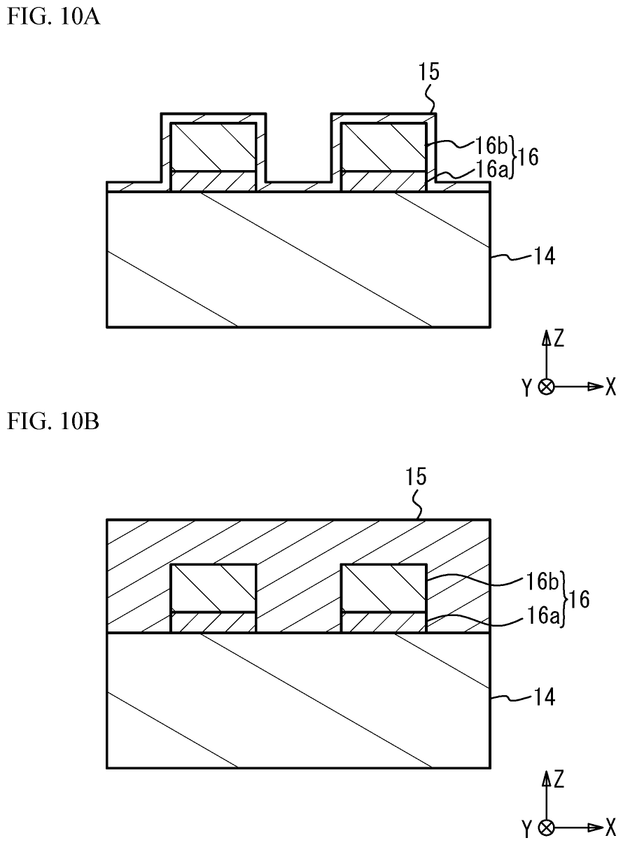

FIG. 10A and FIG. 10B illustrate other exemplary structures of the acoustic wave resonator in the embodiment 1. As illustrated in FIG. 10A, a protective film 15 is provided on the piezoelectric layer 14 so as to cover the electrode fingers 18. The thickness of the protective film 15 is smaller than the thickness of the electrode finger 18. Other configurations are the same as those of FIG. 1B, and the description thereof is omitted. As illustrated in FIG. 10B, the protective film 15 is provided on the piezoelectric layer 14 so as to cover the electrode fingers 18. The thickness of the protective film 15 is larger than the thicknesses of the electrode fingers 18, and the upper surface of the protective film 15 is planarized. The protective film 15 is, for example, an inorganic insulator film such as a silicon oxide film or a silicon nitride film. The support substrate 10 may be provided under the piezoelectric layer 14. At least one of the insulating layers 11 to 13 may be provided between the support substrate 10 and the piezoelectric layer 14. Other configurations are the same as those of FIG. 1B, and the description thereof is omitted.

In the embodiment 1, at least one pair of the comb-shaped electrodes 20 includes a plurality of electrode fingers each having the first layer 16a, which is a titanium nitride layer, and the second layer 16b, which is a metallic layer provided on the first layer 16a. As a result, the TCF can be improved and the variation in the TCF can be reduced even when the thickness T6a of the first layer 16a is made larger than 30 nm as in the experimental results.

In particular, the experimental results can be generalized to the case where an aluminum layer or an aluminum alloy layer is used as the second layer 16b when the experimental results are based on the reason presumed above.

In particular, when the experimental results are due to the reason presumed above, the experimental results can be generalized to the case where a rotated Y-cut lithium tantalate layer is used as the piezoelectric layer 14.

Between the first layer 16a and the piezoelectric layer 14 and/or between the first layer 16a and the second layer 16b, there may be a conductive film that has a thickness smaller than the thickness T6a of the first layer 16a and is made of a material different from those of the first layer 16a and the second layer 16b. However, the first layer 16a is preferably in contact with the piezoelectric layer 14 and the second layer 16b. This configuration can further improve the TCF.

From FIG. 7, the thickness T6a of the first layer 16a is preferably 40 nm or greater, more preferably 50 nm or greater, and further preferably 60 nm or greater. Too thick first layer 16a increases the resistance of the electrode fingers 18. Therefore, the thickness T6a is preferably 200 nm or less, more preferably 150 nm or less, and further preferably 90 nm or less. Further, the thickness T6a is preferably smaller than the thickness T6b.

In the experiment, the first layer 16a was formed by sputtering. When the first layer 16a is formed by sputtering, the ratio of the content percentage of nitrogen in the first layer 16a in atomic % to the sum of the content percentage of titanium in the first layer 16a in atomic % and the content percentage of nitrogen in the first layer 16a in atomic % is generally 0.3 or greater and 0.6 or less. Therefore, when the ratio of the content percentage (atomic %) of nitrogen to the sum of the content percentage (atomic %) of titanium and the content percentage (atomic %) of nitrogen is 0.3 or greater and 0.6 or less, the results of the experiment can be particularly generalized. In addition, titanium nitride is considered thermodynamically stable when X is 0.6 to 1.2 in TiN_{X}. In this case, the ratio of the content percentage (atomic %) of nitrogen to the sum of the content percentage (atomic %) of titanium and the content percentage (atomic %) of nitrogen is 0.38 or greater and 0.55 or less. Therefore, the ratio of the content percentage (atomic %) of nitrogen to the sum of the content percentage (atomic %) of titanium and the content percentage (atomic %) of nitrogen is preferably 0.38 or greater and 0.55 or less.

As illustrated in FIG. 2A, a layer such as a support substrate may not be necessarily provided other than the piezoelectric layer 14. As illustrated in FIG. 2B to FIG. 2D and FIG. 8A to FIG. 9B, the support substrate 10 may be provided below the piezoelectric layer 14. As illustrated in FIG. 2B, FIG. 2C, and FIG. 8A to FIG. 9B, the insulating layers 11 to 13 may be provided between the support substrate 10 and the piezoelectric layer 14. The interface between the interface 30 and the insulating layer 11 may be a rough surface or a mirrored surface.

### Embodiment 2

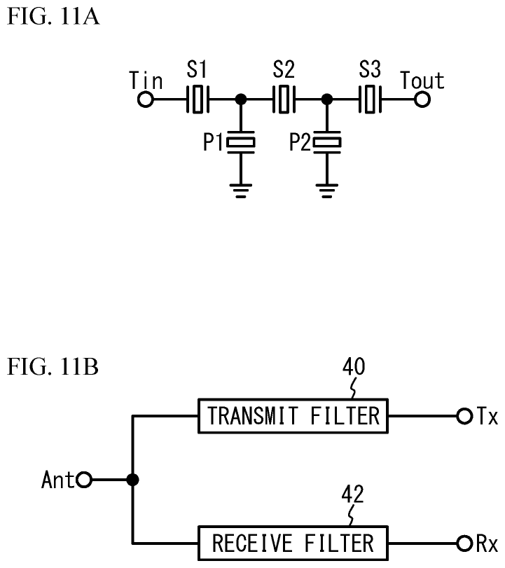

FIG. 11A is a circuit diagram of a filter in accordance with an embodiment 2. As illustrated in FIG. 11A, one or more series resonators S1 to S3 are connected in series between an input terminal Tin and an output terminal Tout. One or more parallel resonators P1 and P2 are connected in parallel between the input terminal Tin and the output terminal Tout. The acoustic wave resonator according to the embodiment 1 may be used as at least one of the following resonators: one or more series resonators S1 to S3 and one or more parallel resonators P1 and P2. The number of resonators of the ladder-type filter can be set as desired. The filter may be a multimode filter having two or more pairs of comb-shaped electrodes.

### First Variation of Embodiment 2

FIG. 11B is a circuit diagram of a duplexer in accordance with a first variation of the embodiment 2. As illustrated in FIG. 11B, a transmit filter 40 is connected between a common terminal Ant and a transmit terminal Tx. A receive filter 42 is connected between the common terminal Ant and a receive terminal Rx. The transmit filter 40 transmits signals in the transmit band among high-frequency signals input from the transmit terminal Tx to the common terminal Ant as transmit signals, and suppresses signals of other frequencies. The receive filter 42 transmits signals in the receive band among high-frequency signals input from the common terminal Ant to the receive terminal Rx as receive signals, and suppresses signals of other frequencies. At least one of the transmit filter 40 or the receive filter 42 may be the filter according to the embodiment 2.

Although the duplexer has been described as an example of the multiplexer, the multiplexer may be a triplexer or a quadplexer.

### Embodiment 3

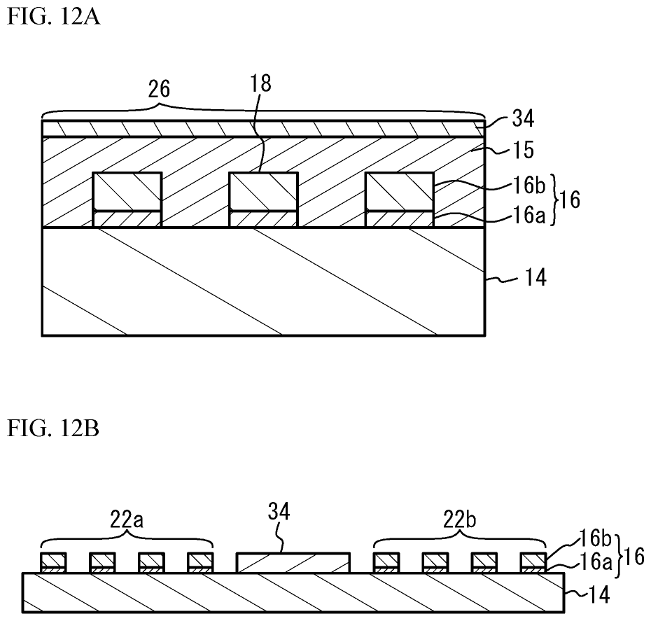

An embodiment 3 is an example in which the acoustic wave device of the embodiment 1 is used in a sensor. FIG. 12A and FIG. 12B are cross-sectional views of a sensor element according to the embodiment 3. As illustrated in FIG. 12A, the protective film 15 is provided on the electrode fingers 18 of the acoustic wave resonator 26, and a sensitive film 34 is provided on the protective film 15. When substances in the gas are adsorbed onto the sensitive film 34, the resonant frequency of the acoustic wave resonator 26 decreases. The substances in the gas can be detected by measuring the resonant frequency of the acoustic wave resonator 26.

As illustrated in FIG. 12B, two IDTs 22a and 22b are provided on the piezoelectric layer 14. The sensitive film 34 is provided on the piezoelectric layer 14 between the IDTs 22a and 22b. When a high-frequency signal is applied to the IDT 22a, an acoustic wave is excited in the piezoelectric layer 14. The acoustic wave propagates through the piezoelectric layer 14 under the sensitive film 34 and is converted into a high-frequency signal at the IDT 22b. When substances in the gas are adsorbed onto the sensitive film 34, the velocity of the acoustic wave propagating through the piezoelectric layer 14 under the sensitive film 34 is decreased. The substances in the gas can be detected by measuring the phase difference between the high-frequency signal applied to the IDT 22a and the high-frequency signal output from the IDT 22b.

As in the embodiment 3, the acoustic wave resonator 26 or the IDT 22 of the embodiment 1 can be used as a sensor element. As in the embodiment 1, the support substrate 10 may be provided below the piezoelectric layer 14. At least one of the insulating layers 11 to 13 may be provided between the support substrate 10 and the piezoelectric layer 14.

The experimental results of FIG. 7 will be discussed again. First, according to the findings of the inventors, the temperature coefficients of the acoustic velocities of titanium and titanium nitride do not vary greatly, and the signs of the temperature coefficients of the acoustic velocities are negative. The sign of the temperature coefficient of the acoustic velocity of lithium tantalate is also negative. The absolute values of the temperature coefficients of the acoustic velocities of titanium and titanium nitride are larger than the absolute value of the temperature coefficient of the acoustic velocity of lithium tantalate.

Based on the above findings, in the case that the first layer 16a is a titanium layer or a titanium nitride layer and the piezoelectric layer 14 is a lithium tantalate substrate, it is considered that when the energy of the acoustic wave is distributed more in the piezoelectric layer 14 of the piezoelectric layer 14 and the first layer 16a, the TCF is less affected by the change in the acoustic velocity in the first layer 16a due to temperature and becomes close to 0. When the thickness T6a of the first layer 16a is small, the energy of the acoustic wave is mainly distributed in the piezoelectric layer 14. Therefore, the absolute value of the TCF is mainly determined by the temperature coefficient of the acoustic velocity of the piezoelectric layer 14. As the thickness T6a of the first layer 16a increases, the absolute value of the TCF increases because the energy of the acoustic wave is distributed in the first layer 16a where the absolute value of the temperature coefficient of the acoustic velocity is large.

The Young's modulus of titanium nitride is greater than the Young's modulus of titanium. Therefore, the acoustic velocity of titanium nitride is higher than the acoustic velocity of titanium. Therefore, when titanium nitride is used as the first layer 16a, more acoustic wave energy is distributed in the piezoelectric layer 14 than when titanium is used as the first layer 16a. Thus, in the embodiment 1 in which the first layer 16a is a titanium nitride layer, the absolute value of the TCF is smaller than that in the comparative example 1 in which the first layer 16a is a titanium layer. In particular, as the thickness T6a of the first layer 16a increases, the absolute value of the TCF increases in the comparative example 1 because the energy of the acoustic wave distributed in the first layer 16a increases. In addition, the variation in the TCF increases. In the embodiment 1, the acoustic velocity in the first layer 16a is high, and the energy of the acoustic wave is easily distributed in the piezoelectric layer 14. Therefore, even when the first layer 16a becomes thick, the absolute value of the TCF does not become as large as in the comparative example 1. In addition, the variation in the TCF does not increase.

Considering the experimental results as the reason that has been rediscussed above, it is sufficient that the sign of the temperature coefficient of the acoustic velocity of the piezoelectric layer 14 is negative and the absolute value of the temperature coefficient of the acoustic velocity of the piezoelectric layer 14 is smaller than the absolute value of the acoustic velocity of titanium nitride. Examples of such a material include lithium niobate in addition to lithium tantalate. Therefore, the experiment results can be generalized to the case where a rotated Y-cut X-propagation lithium tantalate substrate or a rotated Y-cut X-propagation lithium niobate substrate is used as the piezoelectric layer 14.

For the reason rediscussed above, the second layer 16b is not particularly limited and is only required to function as an electrode. Since the second layer 16b functions as a low-resistance layer, the resistivity of the second layer 16b is preferably lower than the resistivity of the first layer 16a. As such a material, the second layer 16b is preferably an aluminum layer, an aluminum alloy layer, a copper layer, or a copper alloy layer.

Based on the results in FIG. 7, the thickness T6a of the first layer 16a is preferably greater than 30 nm. When the thickness T6a is 60 nm, the change in the TCF of the embodiment 1 is smaller than that of the comparative example 1. Therefore, the thickness T6a is more preferably greater than 50 nm, and further preferably 60 nm or greater. To reduce the resistance of the electrode finger 18, the thickness T6a of the first layer 16a is preferably equal to or less than 1 times, more preferably equal to or less than ½ times, further preferably equal to or less than ⅕ times the thickness of the second layer 16b. The thickness T6a is preferably equal to or less than 300 nm. To improve the characteristics of the acoustic wave resonator 26, the sum of the thicknesses T6a and T6b is equal to or greater than 0.05 times the wave length λ of the acoustic wave (2×pitch D) and equal to or less than 0.15 times the wave length λ of the acoustic wave (2×pitch D).

Although the embodiment of the present invention has been described in detail above, the present invention is not limited to the specific embodiment, and various modifications and changes can be made within the scope of the gist of the present invention described in the claims.

What is claimed is:

1. An acoustic wave device comprising:
a piezoelectric layer; and
at least one pair of comb-shaped electrodes provided on the piezoelectric layer, each of the comb-shaped electrodes including electrode fingers each having a first layer and a second layer provided on the first layer, the first layer being a titanium nitride layer with a thickness greater than 50 nm, the second layer being a metal layer.

2. The acoustic wave device according to claim 1, wherein the piezoelectric layer is a rotated Y-cut X-propagation lithium tantalate substrate or a rotated Y-cut X-propagation substrate.

3. The acoustic wave device according to claim 2, wherein the second layer is an aluminum layer, an aluminum alloy layer, a copper layer, or a copper alloy layer.

4. The acoustic wave device according to claim 1, wherein the first layer is in contact with the piezoelectric layer and the second layer.

5. The acoustic wave device according to claim 1, wherein a thickness of the first layer is equal to or less than a thickness of the second layer.

6. The acoustic wave device according to claim 1, wherein a ratio of a content percentage of nitrogen in the first layer in atomic % to a sum of a content percentage of titanium in the first layer in atomic % and a content percentage of nitrogen in the first layer in atomic % is 0.3 or greater and 0.6 or less.

7. The acoustic wave device according to claim 3,
wherein the first layer is in contact with the piezoelectric layer and the electrode fingers,
wherein a thickness of the first layer is equal to or less than a thickness of the second layer, and
wherein a ratio of a content percentage of nitrogen in the first layer in atomic % to a sum of a content percentage of titanium in the first layer in atomic % and a content percentage of nitrogen in the first layer in atomic % is 0.3 or greater and 0.6 or less.

8. The acoustic wave device according to claim 7,
wherein the piezoelectric layer is a rotated Y-cut X-propagation lithium tantalate substrate, and
wherein the second layer is an aluminum layer or an aluminum alloy layer.

9. The acoustic wave device according to claim 1, further comprising a support substrate located under the piezoelectric layer.

10. A filter comprising the acoustic wave device according to claim 1.

11. A multiplexer comprising the filter according to claim 10.
